(19) United States
(12) Patent Application Publication
(10) Pub. No.: US 2014/0042530 A1
(43) Pub. Date: Feb. 13, 2014

(54) SEMICONDUCTOR DEVICE AND METHOD OF FABRICATING THE SAME

(71) Applicants: Min-Kwon CHO, Hwaseong-si (KR); Takayuki GOMI, Seongnam-si (KR); Chan-Ho PARK, Seongnam-si (KR); Nam-Ki CHO, Goyang-si (KR); Won-Sang CHOI, Seoul (KR)

(72) Inventors: Min-Kwon CHO, Hwaseong-si (KR); Takayuki GOMI, Seongnam-si (KR); Chan-Ho PARK, Seongnam-si (KR); Nam-Ki CHO, Goyang-si (KR); Won-Sang CHOI, Seoul (KR)

(21) Appl. No.: 13/963,161

(22) Filed: Aug. 9, 2013

(30) Foreign Application Priority Data
Aug. 13, 2012 (KR) 10-2012-0088498

(51) Int. Cl. H01L 29/06; H01L 29/66; H01L 29/78

(52) U.S. Cl. CPC H01L 29/0619; H01L 29/7827; H01L 29/66666; H01L 29/78
USPC 257/330; 438/270; 257/488; 257/409

(57) ABSTRACT

A semiconductor device includes a substrate including a first region and a second region, a trench-gate transistor in the first region, the trench-gate transistor including a first trench in the substrate, a gate filling at least part of the first trench, and a source in the substrate and on each sidewall of the first trench, a first field diffusion junction in the second region, an interlayer insulating film on the substrate, the interlayer insulating film covering the trench-gate transistor and the first field diffusion junction, a first contact in the first region, the first contact passing through the interlayer insulating film and contacting the source, and a second contact in the second region, the second contact passing through the interlayer insulating film and contacting the first field diffusion junction, the first contact and the second contact having an equal height and including a same material.

### CROSS-REFERENCE TO RELATED APPLICATION

The present application claims priority under 35 U.S.C. §119 to Korean Patent Application No. 10-2012-0088498, filed on Aug. 13, 2012, in the Korean Intellectual Property Office, and entitled: “Semiconductor Device and Method of Fabricating the Same,” which is incorporated by reference herein in its entirety.

### BACKGROUND

1. Field

The present inventive concept relates to a semiconductor device and a method of fabricating the same, and more particularly, to a high-voltage metal oxide semiconductor field-effect transistor (MOSFET) having a trench-gate structure or a planar gate structure and a method of fabricating the same.

2. Description of the Related Art

Examples of high-voltage semiconductor devices include metal oxide semiconductor field-effect transistors (MOSFETs), bipolar transistors, and insulated-gate bipolar transistors (IGBTs). For example, a MOSFET may include a gate formed in a trench of a substrate, a source formed on a side of the substrate, and a drain formed on the other side of the substrate. This structure causes a channel of the MOSFET to be formed in a vertical direction.

A high-voltage semiconductor device may use a field plate in order to improve insulation internal pressure. In the conventional art, an additional process is performed to form the field plate. However, the additional process can undermine price competitiveness of the high-voltage semiconductor device. Therefore, it is required to simplify the process of forming the field plate.

### SUMMARY

Aspects of the present inventive concept provide a semiconductor device which includes a field plate formed in a simplified process.

Aspects of the present inventive concept also provide a fabrication process of the semiconductor device which includes a field plate.

However, aspects of the present inventive concept are not restricted to the one set forth herein. The above and other aspects of the present inventive concept will become more apparent to one of ordinary skill in the art to which the present inventive concept pertains by referencing the detailed description of the present inventive concept given below.

Example embodiments are directed toward a semiconductor device, including a substrate including a first region and a second region, a trench-gate transistor in the first region, the trench-gate transistor including a first trench in the substrate, a gate filling at least part of the first trench, and a source in the substrate and on each sidewall of the first trench, a first field diffusion junction in the second region, an interlayer insulating film, on the substrate, the interlayer insulating film covering the trench-gate transistor and the first field diffusion junction, a first contact in the first region, the first contact passing through the interlayer insulating film and contacting the source, and a second contact in the second region, the second contact passing through the interlayer insulating film and contacting the first field diffusion junction, the first contact and the second contact having an equal height and including a same material.

The first contact and the second contact may be fabricated simultaneously.

Each of the first contact and the second contact may further pass through part of the substrate.

The semiconductor device may further include a source metal on the first contact and a field plate on the second contact, the source metal and the field plate having an equal thickness and include a same material.

The semiconductor device may further include a second field diffusion junction in the second region, the second field diffusion junction being interposed between the trench-gate transistor and the first field diffusion junction.

The semiconductor device may further include a third contact in the second region, the third contact passing through the interlayer insulating film and through part of the substrate to contact the second field diffusion junction.

A surface of the interlayer insulating film may be planarized.

The semiconductor device may further include a body region around the gate in the first region, the source being in the body region.

The body region may have a first depth, and the first field diffusion junction has a second depth different from the first depth.

The body region may have a first concentration, and the first field diffusion junction may have a second concentration different from the first concentration.

The body region may be formed to a first depth and a first concentration, and the first field diffusion junction may be formed to a second depth which is greater than the first depth and to a second concentration which is lower than the first concentration.

The body region may have a first depth and a first concentration, and the first field diffusion junction may have a second depth equal to the first depth and a second concentration higher than the first concentration.

The semiconductor device may further include a high concentration body region in the body region, the high concentration body region contacting a bottom surface of a contact hole.

The semiconductor device may further include a gate connector in the first region and configured to provide a gate voltage to the gate, the gate connector including a second trench in the substrate and a conductor filling at least part of the second trench.

The interlayer insulating film may cover the gate connector and further comprises a third contact, the third contact passing through the interlayer insulating film and through part of the conductor to contact the conductor.

The first through third contacts may have equal heights and include a same material.

The semiconductor device may further include a source metal on the first contact, a field plate on the second contact, and a gate metal on the third contact, the source metal, the field plate, and the gate metal having equal thicknesses and including a same material.

The semiconductor device may further include a connection junction in the first region, the gate connection being in the connection junction.

The connection junction and the first field diffusion junction may have an equal depth and an equal concentration.

A semiconductor system may include a transformer, and a switching device connected to a secondary winding of the transformer, the switching device including the semiconductor device.

Example embodiments are also directed toward a semiconductor device, including a substrate including a first region and a second region, a trench-gate transistor in the first region, the trench-gate transistor including a first trench in the substrate, a gate filling at least part of the first trench, and a source in the substrate and on each sidewall of the first trench, an interlayer insulating film on the first region, the interlayer insulating film covering the trench-gate transistor, a first field diffusion junction in the second region, a field plate on the first field diffusion junction, and a field plate insulating film between the first field diffusion junction and the field plate, the field plate insulating film having a thickness equal to a thickness of the interlayer insulating film, and including a same material as the interlayer insulating film.

Example embodiments are also directed toward a semiconductor device, including a substrate including a first region and a second region, a trench-gate transistor in the first region, the trench-gate transistor including a first trench in the substrate, a gate filling at least part of the first trench, and a source in the substrate and on each sidewall of the first trench, a connection junction in the first region, a gate connector in the connection junction of the first region and configured to provide a gate voltage to the gate, the gate connector including a second trench in the substrate and a conductor filling at least part of the second trench, and a first field diffusion junction in the second region, the connection junction and the first field diffusion junction having an equal depth and an equal concentration.

Example embodiments are also directed toward a method of fabricating a semiconductor device, the method including providing a substrate including a first region and a second region, forming a body region in the first region and a first field diffusion junction in the second region, forming a transistor in the first region, the transistor including a gate and a source in the substrate and around the gate, forming an interlayer insulating film on the substrate to cover the transistor and the first field diffusion junction, forming a first contact in the first region to pass through the interlayer insulating film and contact the source, and forming a second contact in the second region to pass through the interlayer insulating film and contact the first field diffusion junction, the first contact and the second contact being formed simultaneously.

Forming the transistor may include forming a trench-gate transistor, the trench-gate transistor including a first trench formed in the substrate, the gate filing at least part of the first trench, and the source in the substrate and on each sidewall of the first trench.

Example embodiments are also directed toward a semiconductor device, including a substrate including an active region and a termination region, the substrate including a second conductivity type, pillars in the active region and in the termination region, the pillars including a first conductivity type, an interlayer insulating film on the active region, and a field plate on the termination region, the field plate having a thickness equal to a thickness of the interlayer insulating film, and including a same material as the interlayer insulating film.

Example embodiments are also directed toward a semiconductor device, including a substrate including a first region and a second region, a semiconductor device, including a substrate including a first region and a second region, a transistor in the first region, a first field diffusion junction in the second region, an interlayer insulating film on the substrate, the interlayer insulating film continuously extending to cover the transistor and the first field diffusion junction, an upper surface of the interlayer insulating film above the transistor and the first field diffusion junction being completely parallel to a bottom of the substrate, a first contact in the first region, the first contact passing through the interlayer insulating film to contact a source of the transistor, and a second contact in the second region, the second contact passing through the interlayer insulating film to contact the first field diffusion junction, the first contact and the second contact having an equal height and including a same material.

An entire surface of the interlayer insulating film may be flat and parallel to a bottom of the substrate.

Upper surfaces of the first and second contacts may be level with the upper surface of the interlayer insulating film.

The semiconductor device may further include a source metal on the first contact and a field plate on the second contact, the source metal and the field plate having an equal thickness and include a same material.

The source metal may contact the first contact and the interlayer insulating film, and the field plate may contact the second contact and the interlayer insulating film.

### BRIEF DESCRIPTION OF THE DRAWINGS

Features will become apparent to those of ordinary skill in the art by describing in detail exemplary embodiments with reference to the attached drawings, in which:

FIG. 1 illustrates a plan view of a semiconductor device according to a first embodiment.

FIG. 2 illustrates a cross-sectional view taken along the line A-A of FIG. 1.

FIG. 3 illustrates a cross-sectional view of a semiconductor device according to a second embodiment.

FIG. 4 illustrates a cross-sectional view of a semiconductor device according to a third embodiment.

FIG. 5 illustrates a cross-sectional view of a semiconductor device according to a fourth embodiment.

FIG. 6 illustrates a cross-sectional view of a semiconductor device according to a fifth embodiment.

FIG. 7 illustrates a cross-sectional view of a semiconductor device according to a sixth embodiment.

FIG. 8A illustrates a cross-sectional view of a semiconductor device according to a seventh embodiment.

FIG. 8B is a cross-sectional view of a semiconductor device according to an eighth embodiment.

FIG. 9A illustrates an exemplary circuit diagram of a semiconductor system including a semiconductor device according to some embodiments.

FIG. 9B illustrates an exemplary block diagram of an electronic system including a semiconductor system according to some embodiments.

FIGS. 10A and 10B illustrate exemplary semiconductor systems according to some embodiments.

FIGS. 11 through 15 illustrate cross-sectional views of stages in a method of fabricating a semiconductor device according to some embodiments.

FIG. 16 illustrates a cross-sectional of an intermediate stage in a method of fabricating a semiconductor device according other embodiments.

FIG. 17 illustrates a cross-sectional of an intermediate stage in a method of fabricating a semiconductor device according other embodiments.

### DETAILED DESCRIPTION

Advantages and features of example embodiments and methods of accomplishing the same may be understood more readily by reference to the following detailed description of preferred embodiments and the accompanying drawings. The example embodiments may, however, be embodied in many different forms and should not be construed as being limited to the embodiments set forth herein. Rather, these embodiments are provided so that this disclosure will be thorough and complete and will fully convey the concept of the invention to those skilled in the art, and example embodiments will only be defined by the appended claims. Thus, in some embodiments, well-known methods, procedures, components, and circuitry have not been described in detail to avoid unnecessarily obscuring aspects of the present invention.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “comprising,” when used in this specification, specify the presence of the stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

If a depth (height, thickness, or width) of element A is equal to a depth (height, thickness, or width) of element B, it means that the depth (height, thickness, or width) of element A is completely equal to the depth (height, thickness, or width) of element B or that there is a difference equivalent to a processing error.

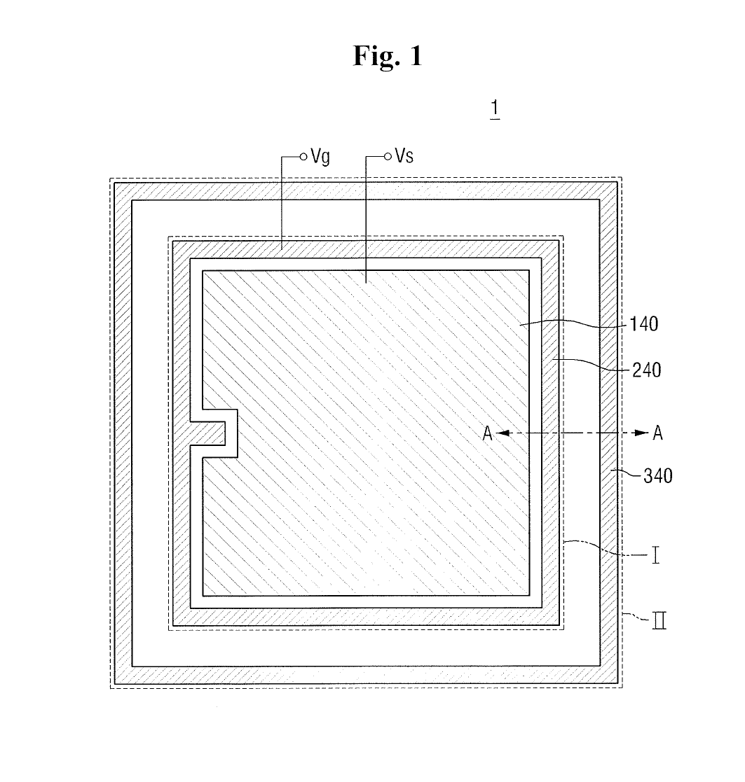

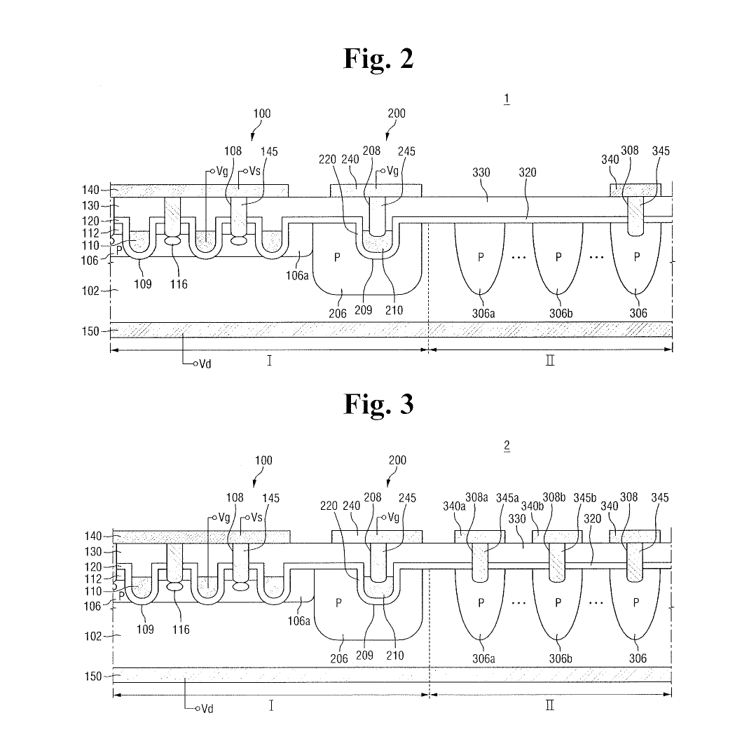

FIG. 1 illustrates a plan view of a semiconductor device 1 according to a first embodiment. FIG. 2 is a cross-sectional view taken along the line A-A of FIG. 1.

Referring to FIGS. 1 and 2, in the semiconductor device 1 according to the first embodiment, a first region I and a second region II are defined in a substrate 102. The first region I may be, but is not limited to, an active region, and the second region II may be, but is not limited to, a termination region.

The substrate 102 may include a base substrate and an epitaxial layer grown on the base substrate. However, the present inventive concept is not limited thereto, e.g., the substrate 102 may include the base substrate only. The substrate 102 may be, e.g., a silicon substrate, a gallium arsenide substrate, a silicon germanium substrate, a ceramic substrate, a quartz substrate or a glass substrate for displays or may be a semiconductor on insulator (SOI) substrate. In the following description, a silicon substrate will be used as an example. In addition, the substrate 102 may be of a second conductivity type (e.g., an N type).

A trench-gate transistor 100 and a gate connector 200 may be formed in the first region I.

The trench-gate transistor 100 may include a body region 106, a first contact hole 108, a first trench 109, a gate 110, a source 112, a high concentration body region 116, a first contact 145, a source metal 140, and a drain metal 150.

The first trench 109 may be formed in the substrate 102. A gate insulating film 120 may be formed along a top surface of the substrate 102 and along sidewalls and a bottom surface of the first trench 109. The gate insulating film 120 may include at least one of, e.g., a silicon oxide film, a silicon nitride film, a silicon oxynitride film, and a high-k material. The high-k material may include at least one of, e.g., HfO₂, ZrO₂, and Ta₂O₅.

The gate 110 may be formed in the first trench 109 to fill the first trench 109 not completely but partially. That is, the gate 110 may be recessed. The gate 110 may be formed using, but not limited to, polysilicon. The gate 110 is connected to the gate connector 200. A gate voltage Vg may be delivered to the gate 110 via the gate connector 200. The gate connector 200 will be described in detail later.

The body region 106 may be formed in a region between adjacent first trenches 109 (i.e., in a region between adjacent gates 110). The body region 106 may be of a first conductivity type (e.g., a P type) which is different from the second conductivity type (e.g., the N type).

As shown in the drawings, a depth from a top surface of the substrate 102 to a bottom surface of the first trench 109 may be greater than a depth from the top surface of the substrate 102 to the body region 106.

In detail, in the trench-gate transistor 100, an electric field may be concentrated in a lower portion of the first trench 109, thereby lowering insulation internal pressure. Additionally, when the depth from the top surface of the substrate 102 to the bottom surface of the first trench 109 is smaller than the depth from the top surface of the substrate 102 to the body region 106, a threshold voltage may increase or an open defect may occur. Further, if the depth from the top surface of the substrate 102 to the bottom surface of the first trench 109 is increased too much to prevent the above problems, concentration of the electric field in the lower portion of the first trench 109 may increase, so a drift region may be reduced. As a result, it may be difficult to form the insulation internal pressure. Therefore, it is required to optimize the relationship between the depth from the top surface of the substrate 102 to the bottom surface of the first trench 109 and the depth from the top surface of the substrate 102 to the body region 106. For example, the depth from the top surface of the substrate 102 to the bottom surface of the first trench 109 may be adjusted to be about 0 to about 0.5 μm greater than the depth from the top surface of the substrate 102 to the body region 106.

The source 112 is formed on each sidewall of the first trench 109 and partially overlaps the gate 110. The source 112 may be of the second conductivity type (e.g., the N type). The source 112 may be, but is not limited to, tilted. In this case, the source 112 may be formed by implanting impurities at an angle.

An interlayer insulating film 130 may be formed on the whole surface of the substrate 102. Specifically, the interlayer insulating film 130 may be formed on the substrate 102 to fill the first trench 109 and may be formed on the gate insulating film 120. The interlayer insulating film 130 may be, but is not limited to, a silicon oxide film.

The first contact hole 108 may be formed in a region between adjacent first trenches 109 (i.e., a region between adjacent gates 110). The first contact hole 108 may pass through the interlayer insulating film 130, the gate insulating film 120, and part of the substrate 102.

The first contact 145 is formed in the first contact hole 108 to contact the source 112.

The source metal 140 is formed on the interlayer insulating film 130 and the first contact 108. The source metal 140 is electrically connected to the source 112 and provides a source voltage Vs to the source 112. The source metal 140 may be, but is not limited to, plate-shaped as shown in FIG. 1. The source metal 140 may include, but not limited to, at least one of aluminum, copper, tungsten, and titanium.

A surface of the interlayer insulating film 130 may be planarized. That is, since the interlayer insulating film 130 has a flat surface, a surface of the source metal 140 formed on the surface of the interlayer insulating film 130 may also be flat. The flat surface of the source metal 140 can reduce the probability that a defect will occur when conductors (e.g., wire bonding) for external connection are formed on the surface of the source metal 140.

The high concentration body region 116 is formed under the first contact hole 108 and between adjacent sources 112. The high concentration body region 116 may be of the first conductivity type (e.g., the P type) and may have a higher concentration than the body region 106. The high concentration body region 116 is designed to improve off-switch characteristics of a semiconductor device (i.e., a MOSFET).

The drain metal 150 may be formed on a backside of the substrate 102, i.e., on an opposite surface of the substrate 102 relative to the source metal 140. However, the present inventive concept is not limited thereto. The drain metal 150 may include, but not limited to, at least one of aluminum, copper, tungsten, and titanium.

The gate connector 200 may include a second trench 209, an insulating film 220, a conductor 210, a second contact hole 208, a second contact 245, and a gate metal 240.

The second trench 209 may be formed in the substrate 102. The second trench 209 may be fabricated at the same time as the first trench 109. Therefore, a depth of the second trench 209 may be equal to a depth of the first trench 109.

The insulating film 220 is conformally formed along sidewalls and a bottom surface of the second trench 209. The insulating film 220 may be fabricated at the same time as the gate insulating film 120. That is, the insulating film 220 and the gate insulating film 120 may be formed of the same material and to an equal thickness.

The conductor 210 may be formed in the second trench 209 to fill the second trench 209 not completely but partially. The conductor 210 may be fabricated at the same time as the gate 110. That is, the conductor 210 and the gate 110 may be formed of the same material and to an equal thickness.

The second contact hole 208 may pass through the interlayer insulating film 130 and part of the conductor 210. The second contact hole 208 may be fabricated at the same time as the first contact hole 108. That is, the first contact hole 108 and the second contact hole 208 may be formed to an equal depth.

The second contact 245 is formed in the second contact hole 208. The second contact 245 may be fabricated at the same time as the first contact 145. That is, the first contact 145 and the second contact 245 may be formed of the same material and to an equal thickness.

The gate metal 240 is formed on, e.g., directly on, the interlayer insulating film 130 and the second contact 245. The gate metal 240 may surround, e.g., completely surround a perimeter of, the source metal 140 as shown in FIG. 1. However, the present inventive concept is not limited thereto. The conductor 210 is electrically connected to the gate metal 240 via the second contact 245. The gate voltage Vg may be delivered to the conductor 210 and the gate 110 via the gate metal 240.

The gate connector 200 is formed within a connection junction 206. The connection junction 206 may be of the first conductivity type (e.g., the P type). As shown in the drawings, the connection junction 206 may be deeper than the body region 106 relative to the top surface of the substrate 102. However, the concentration of the connection junction 206 may be lower than that of the body region 106.

Field diffusion junctions 306, 306a, and 306b, a field plate insulating film 330, a third contact hole 308, a third contact 345, and a field plate 340 may be formed in the second region II.

The field diffusion junctions 306, 306a, and 306b may be of the first conductivity type (e.g., the P type). As shown in the drawings, each of the field diffusion junctions 306, 306a, and 306b may be deeper than the body region 106. In addition, the concentration of the field diffusion junctions 306, 306a, and 306b may be lower than that of the body region 106. The field diffusion junctions 306, 306a, and 306b configured as described above can effectively diffuse an electric field formed in the first region I.

The field diffusion junctions 306, 306a, and 306b may be fabricated at the same time as the connection junction 206. That is, the field diffusion junctions 306, 306a, and 306b, and the connection junction 206 may be formed to an equal depth and to an equal concentration.

As shown in the drawings, a plurality of field diffusion junctions 306, 306a, and 306b may be formed. Some of the field diffusion junctions 306, 306a, and 306b, e.g., field diffusion junctions 306a and 306b, may not be connected to the field plate 340.

The field plate insulating film 330 may be fabricated at the same time as the interlayer insulating film 130. That is, the field plate insulating film 330 and the interlayer insulating film 130 may be formed of the same material and to an equal thickness. In other words, the interlayer insulating film formed in the second region II can be used as the field plate insulating film 330.

The third contact hole 308 may pass through the field plate insulating film 330 (i.e., the interlayer insulating film) and part of the substrate 102. The third contact hole 308 may be fabricated at the same time as the first contact hole 108 and the second contact hole 208. That is, the first contact hole 108, the second contact hole 208, and the third contact hole 308 may be formed to an equal depth. However, the present inventive concept is not limited thereto. For example, only the first contact hole 108 and the third contact hole 308 may be fabricated simultaneously. In this case, the first contact hole 108 and the third contact hole 308 may be formed to an equal depth.

The third contact 345 is formed in the third contact hole 308 to contact the field diffusion junction 306. The third contact 345 may be fabricated at the same time as the first contact 145 and the second contact 245. That is, the first contact 145, the second contact 245, and the third contact 345 may be formed to an equal height and of the same material. However, the present inventive concept is not limited thereto. For example, only the first contact 145 and the third contact 345 may be fabricated simultaneously. In this case, the first contact 145 and the third contact 345 may be formed to an equal height and of the same material.

The field plate 340 is formed on the field plate insulating film 330 (i.e., the interlayer insulating film) and the third contact 308. The field plate 340 may surround the gate metal 240 as shown in FIG. 1. However, the present inventive concept is not limited thereto. The field plate 340 may be floating.

When the source voltage Vg, a drain voltage Vd, and the gate voltage Vg at a certain level are applied to the trench-gate transistor 100, the trench-gate transistor 100 begins to operate. At this time, an electric field may be concentrated around an edge (e.g., 106a) of the trench-gate transistor 100. The electric field concentrated around the edge may reduce a breakdown voltage. However, in the semiconductor device 1 according to the first embodiment of the present inventive concept, the concentrated electric field may diffuse along the field diffusion junctions 306, 306a, and 306b. In addition, the field plate 340 may facilitate the diffusion of the electric field.

In the semiconductor device 1 according to the first embodiment of the present inventive concept, the field plate insulating film 330 is formed when the interlayer insulating film 130 is formed. In other words, the interlayer insulating film 130 is used as the field plate insulating film 330. That is, no additional, e.g., separate, process and no additional, e.g., separate, mask are required to form the field plate insulating film 330. In addition, when the first contact hole 108 and the first contact 145 are formed, the third contact hole 308 and the third contact 345 are also formed. That is, no additional process and no additional mask are required to form the third contact hole 308 and the third contact 345. Further, when the connection junction 206 is formed, the field diffusion junction 306 is also formed. That is, no additional process and no additional mask are required to form the field diffusion junction 306. In summary, no additional processes and no additional masks are required to form the field plate insulating film 330, the third contact hole 308, the third contact 345, and the field diffusion junctions 306, 306a, and 306b in the second region II. This can simplify the fabrication process and improve price competitiveness.

FIG. 3 illustrates a cross-sectional view of a semiconductor device 2 according to a second embodiment. For simplicity, the following description will focus on differences between FIGS. 2 and 3.

Referring to FIG. 3, in the semiconductor device 2 according to the second embodiment, field diffusion junctions 306a and 306b may be connected to field plates 340a and 340b via third contacts 345a and 345b, respectively. The field diffusion junctions 306a and 306b connected to the field plates 340a and 340b can facilitate the diffusion of an electric field.

Third contact holes 308a and 308b may pass through the field plate insulating film 330 (i.e., an interlayer insulating film) and part of the substrate 102. The third contacts 345a and 345b are formed in the third contact holes 308a and 308b to contact the field diffusion junctions 306a and 306b, respectively. The field plates 340a and 340b are formed on the field plate insulating film 330 and the third contacts 345a and 345b.

The third contact holes 308a and 308b may be fabricated at the same time as the third contact hole 308. The third contacts 345a and 345b may be fabricated at the same time as the third contact 345. The field plates 340a and 340b may be fabricated at the same time as the field plate 340.

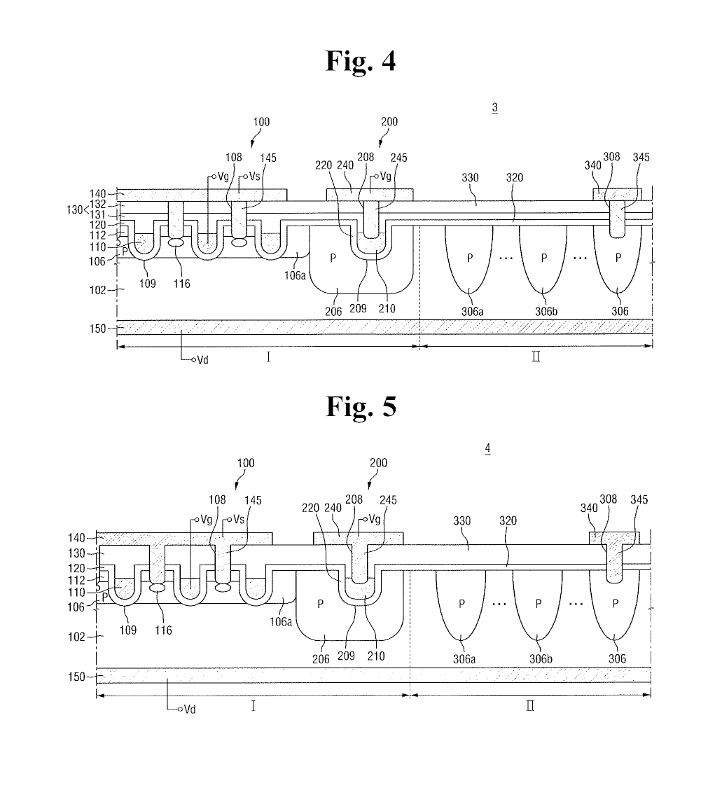

FIG. 4 illustrates a cross-sectional view of a semiconductor device 3 according to a third embodiment. For simplicity, the following description will focus on differences between FIGS. 2 and 4.

Referring to FIG. 4, in the semiconductor device 3 according to the third embodiment, the interlayer insulating film 130 may include a plurality of insulating films, e.g., lower and upper insulating films 131 and 132. For example, the lower insulating film 131 may include a material having superior characteristics (e.g., insulating characteristics, gap-filling characteristics, etc.), and the upper insulating film 132 may include a material that can be formed fast and thick.

FIG. 5 illustrates a cross-sectional view of a semiconductor device 4 according to a fourth embodiment. For simplicity, the following description will focus on differences between FIGS. 2 and 5.

Referring to FIG. 5, in the semiconductor device 4 according to the fourth embodiment, the first contact 145 and the source metal 140, the second contact 245 and the gate metal 240, the third contact 345 and the field plate 340 may be fabricated using a damascene method. For example, the first contact 145 and the source metal 140, the second contact 245 and the gate metal 240, and the third contact 345 and the field plate 340 may be made of copper.

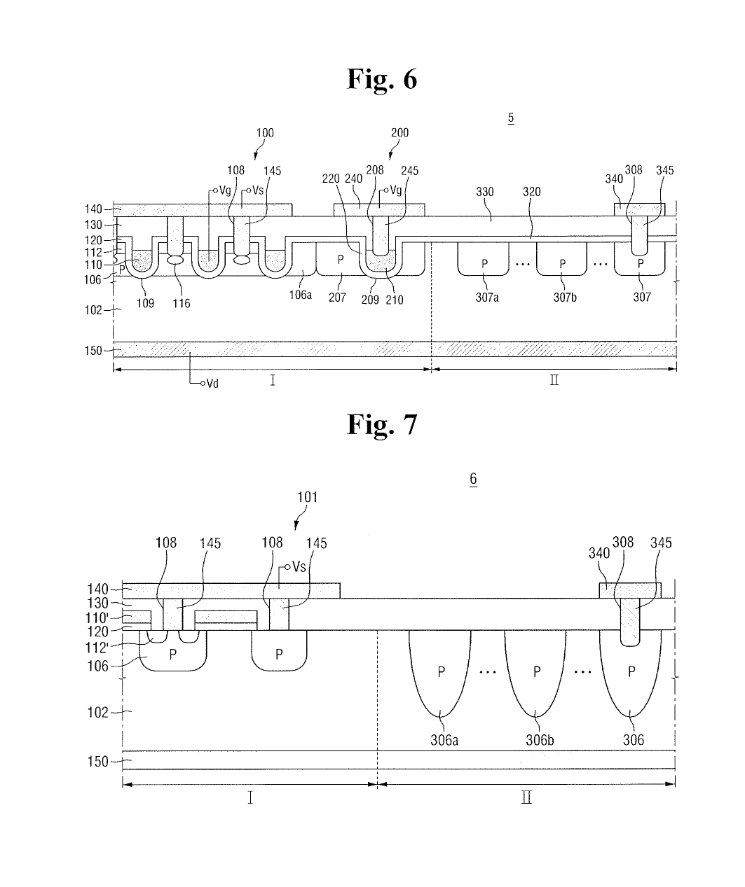

FIG. 6 illustrates a cross-sectional view of a semiconductor device 5 according to a fifth embodiment. For simplicity, the following description will focus on differences between FIGS. 2 and 6.

Referring to FIG. 6, in the semiconductor device 5 according to the fifth embodiment, a depth of field diffusion junctions 307, 307a, and 307b may be equal to a depth of the body region 106. In addition, a depth of a connection junction 207 may be equal to the depth of the body region 106. However, the concentration of each of the field diffusion junctions 307, 307a, and 307b may be higher than that of the body region 106. In addition, the concentration of the connection junction 207 may be higher than that of the body region 106.

FIG. 7 illustrates a cross-sectional view of a semiconductor device 6 according to a sixth embodiment. For simplicity, the following description will focus on differences between FIGS. 2 and 7.

Referring to FIG. 7, in the semiconductor device 6 according to the sixth embodiment, a planar transistor 101, i.e., as opposed to the trench-gate transistor 100, may be formed in the first region I. The planar transistor 101 may include a gate 110′ formed on the substrate 102, and a source 112′ formed in the substrate 102 to contact the gate 110.

When the interlayer insulating film 130 is formed, the field plate insulating film 330 is also formed. In other words, the interlayer insulating film 130 is used as the field plate insulating film 330. In addition, when the first contact hole 108 and the first contact 145 are formed, the third contact hole 308 and the third contact 345 are also formed.

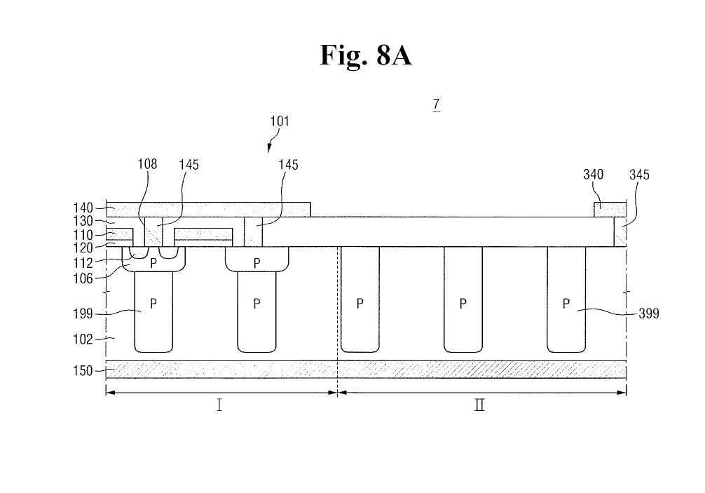

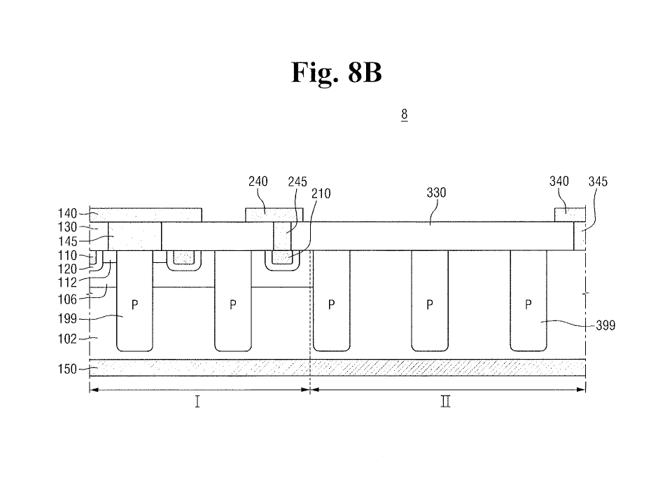

FIG. 8A illustrates a cross-sectional view of a semiconductor device 7 with a planar transistor according to a seventh embodiment. FIG. 8B is a cross-sectional view of a semiconductor device 8 with a trench-gate transistor according to an eighth embodiment.

Referring to FIGS. 8A and 8B, in the semiconductor devices 7 and 8 according to the seventh and eighth embodiments, impurity pillars 199 and 399 of the first conductivity type (e.g., a P type) are formed in the substrate 102 to extend in a vertical direction. Since the substrate 102 is of the second conductivity type (e.g., an N type), it may look as if the impurity pillars 199 and 399 of the first conductivity type and impurity pillars of the second conductivity type are alternately repeated in the substrate 102 as shown in the drawings. That is, PN may be repeated. Here, a depletion layer may be formed at a PN junction. The depletion layer may easily expand laterally in a narrow space between P and N. That is, since a drift region completely turns into a depletion layer at a low voltage, an electric field is not concentrated in one area. Therefore, even if the drift region through which an electric current flows is designed to have a high concentration, a high breakdown voltage may be secured, which, in turn, improves forward characteristics of the semiconductor devices 7 and 8.

The pillars 199 in the first region I and the pillars 399 in the second region II may be formed simultaneously. Therefore, the pillars 199 and 399 may be formed to substantially an equal depth and to an equal concentration.

The semiconductor device 7 including the planar transistor may employ the pillars 199 and 399 as shown in FIG. 8A, and the semiconductor device 8 including the trench-gate transistor may employ the pillars 199 and 399 as shown in FIG. 8B. When the interlayer insulating film 130 is formed, the field plate insulating film 330 is also formed. In other words, the interlayer insulating film 130 is used as the field plate insulating film 330. The interlayer insulating film 130 and the field plate insulating film 330 may be formed to an equal thickness and of the same material.

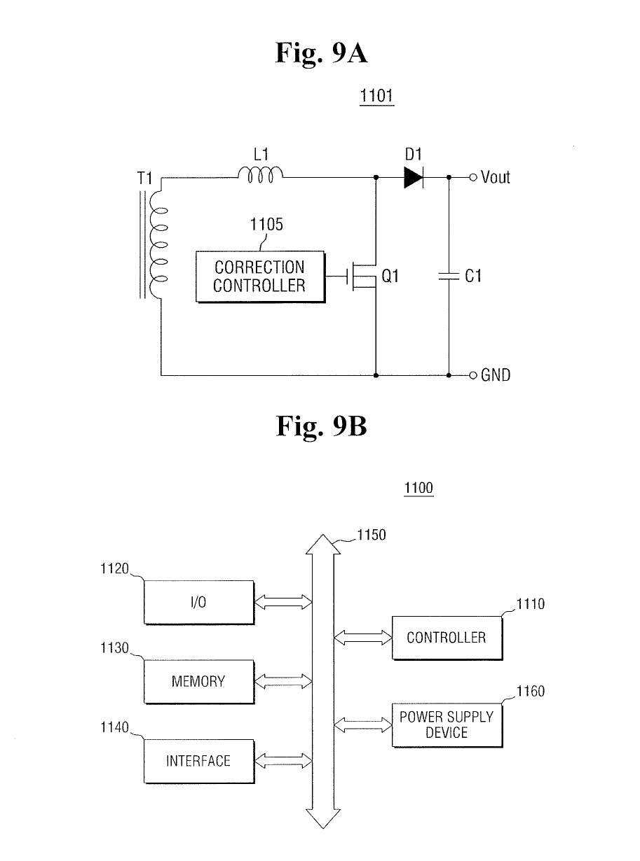

FIG. 9A illustrates an exemplary circuit diagram of a semiconductor system 1101 including a semiconductor device according to some embodiments. For example, the semiconductor system 1101 may be a power supply device.

Referring to FIG. 9A, the semiconductor system 1101 including a semiconductor device according to some embodiments may include a transformer T1, a choke coil L1, a rectifier diode D1, a smoothing condenser C1, a switching transistor Q1, and a correction controller 1105.

The choke coil L1 is connected to a secondary winding of the transformer T1 so as to correct distortions such as current overlaps. The switching transistor Q1 switches a voltage flowing through the choke coil L1 to an output terminal. The correction controller 1105 turns the switching transistor Q1 on or off by providing a control signal to the switching transistor Q1. The rectifier diode D1 rectifies a voltage received through the choke coil L1. The smoothing condenser C1 smoothes the voltage rectified by the rectifier diode D1 and outputs the smoothed voltage.

The correction controller 1105 may switch the switching transistor Q1 on or off faster than a frequency of an input voltage, and may adjust the operation time of the switching transistor Q1 to be proportional to the magnitude of the input voltage. In so doing, the amount of current flowing through the choke coil L1 may be controlled according to the switching cycle of the correction controller 1105. As a result, a power factor can be corrected.

At least one of the semiconductor devices according to the embodiments of FIGS. 1 through 7 may be used as the switching transistor Q1. While a case where at least one of the semiconductor devices according to the embodiments of FIGS. 1 through 7 is used in a power supply device has been described above as an example, example embodiments are not limited to this case.

FIG. 9B illustrates an exemplary block diagram of an electronic system 1100 including a semiconductor system according to some embodiments.

Referring to FIG. 9B, the electronic system 1100 according to the embodiments may include a controller 1110, an input/output (I/O) device 1120, a memory device 1130, an interface 1140, a power supply device 1160, and a bus 1150. The controller 1110, the I/O device 1120, the memory device 1130, and/or the interface 1140 may be coupled to each other through the bus 1150. The bus 1150 corresponds to a path through which data transfer.

The controller 1110 may include at least one of, e.g., a microprocessor, a digital signal processor, a microcontroller, and logic elements capable of performing similar functions to those of the above elements. The I/O device 1120 may include, e.g., a keypad, a keyboard, and/or a display device. The memory device 1130 may store data and/or commands. The interface 1140 may transmit data to a communication network and/or receive data from the communication network. The interface 1140 can be in a wired or wireless form. For example, the interface 1140 may be an antenna or a wired/wireless transceiver. Although not shown in the drawing, the electronic system 1100 may further include a high-speed DRAM and/or SRAM as an operation memory for improving the operation of the controller 1110. A fin field-effect transistor according to embodiments may be provided within the memory device 1130 or may be provided as a component of the controller 1110 or the I/O device 1120. The power supply device 1160 may convert power received from an external source and provide the converted power to the components 1110 through 1140. One or more power supply devices 1160 may be included in the electronic system 1100. The power supply device 1160 may be the semiconductor system 1101 described above with reference to FIG. 9A.

The electronic system 1100 can be applied to, e.g., a personal digital assistant (PDA), a portable computer, a web tablet, a wireless phone, a mobile phone, a digital music player, a memory card, and all electronic products that can transmit and/or receive information in a wireless environment.

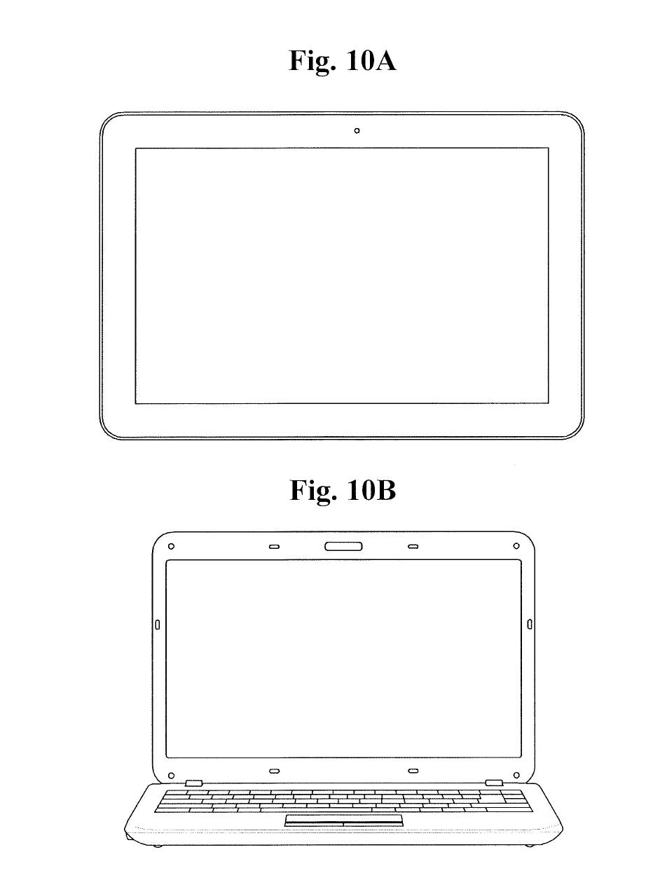

FIGS. 10A and 10B illustrate exemplary semiconductor systems to which a semiconductor device according to some embodiments may be applied. FIG. 10A shows a tablet PC, and FIG. 10B shows a notebook computer. It is obvious to those of ordinary skill in the art that the semiconductor device according to embodiments may also be applicable to other integrated circuit devices not shown in the drawings.

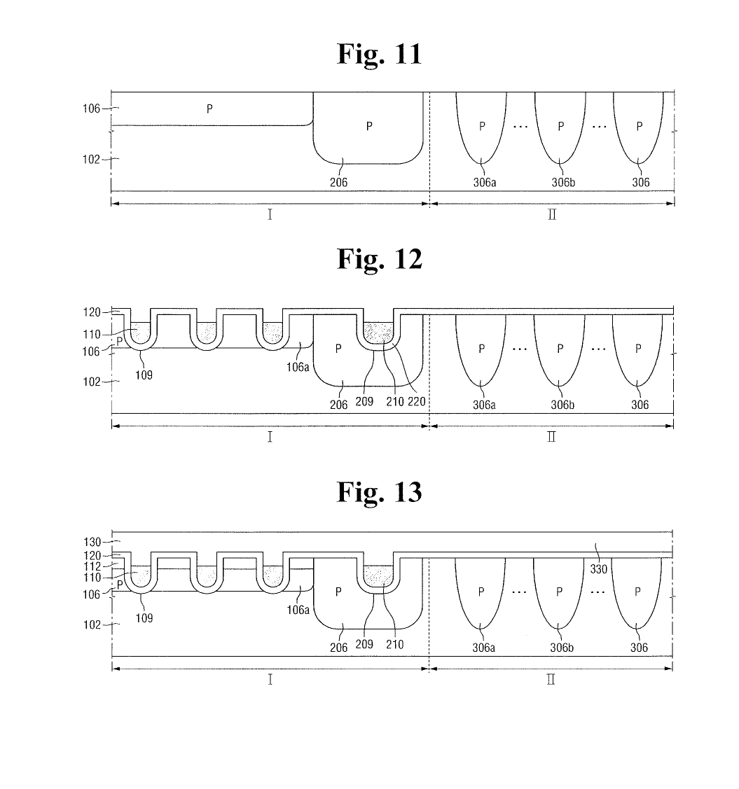

A method of fabricating the semiconductor device according to the first embodiment will now be described with reference to FIGS. 2 and 11-15. FIGS. 11 through 15 are cross-sectional views illustrating intermediate stages in a method of fabricating the semiconductor device according to the first embodiment.

Referring to FIG. 11, the body region 106 is formed by implanting impurities of the first conductivity into the substrate 102. Then, the connection junction 206 and field diffusion junctions 306, 306a, and 306b are formed by implanting impurities of the first conductivity into the substrate 102. As described above, each of the connection junction 206 and the field diffusion junctions 306, 306a, and 306b may be formed deeper than the body region 106, and may have a lower concentration than the body region 106. That is, the connection junction 206 and the field diffusion junctions 306, 306a, and 306b may be implanted with a higher energy and to a lower concentration than the body region 106.

Referring to FIG. 12, the first trench 109 and the second trench 209 are formed simultaneously in the substrate 102. Then, the gate insulating film 120 is formed along a top surface of the substrate 102 and along sidewalls and a bottom surface of the first trench 109. The insulating film 220 is formed along sidewalls and a bottom surface of the second trench 209. The gate insulating film 120 and the insulating film 220 are formed simultaneously, e.g., as a single continuous layer illustrated in FIG. 12.

Then, the gate 110 is formed in the first trench 109 to fill the first trench 109 not completely but partially. The conductor 210 is formed in the second trench 209 to fill the second trench 209 not completely but partially. The gate 110 and the conductor 210 may be, but are not limited to, polysilicon. The gate 110 and the conductor 210 are formed simultaneously.

Referring to FIG. 13, the source 112 is formed by implanting impurities of the second conductivity type. Then, the interlayer insulating film 130 is formed on the first region I, and the field plate insulating film 330 is formed on the second region II. That is, the interlayer insulating film 130 and the field plate insulating film 330 are formed simultaneously. The interlayer insulating film 130 and the field plate insulating film 330 may be formed to an equal thickness and of the same material. The interlayer insulating film 130 and the field plate insulating film 330 may be, but are not limited to, a silicon oxide film. Next, a surface of the interlayer insulating film 130 is planarized by, e.g., chemical mechanical polishing (CMP).

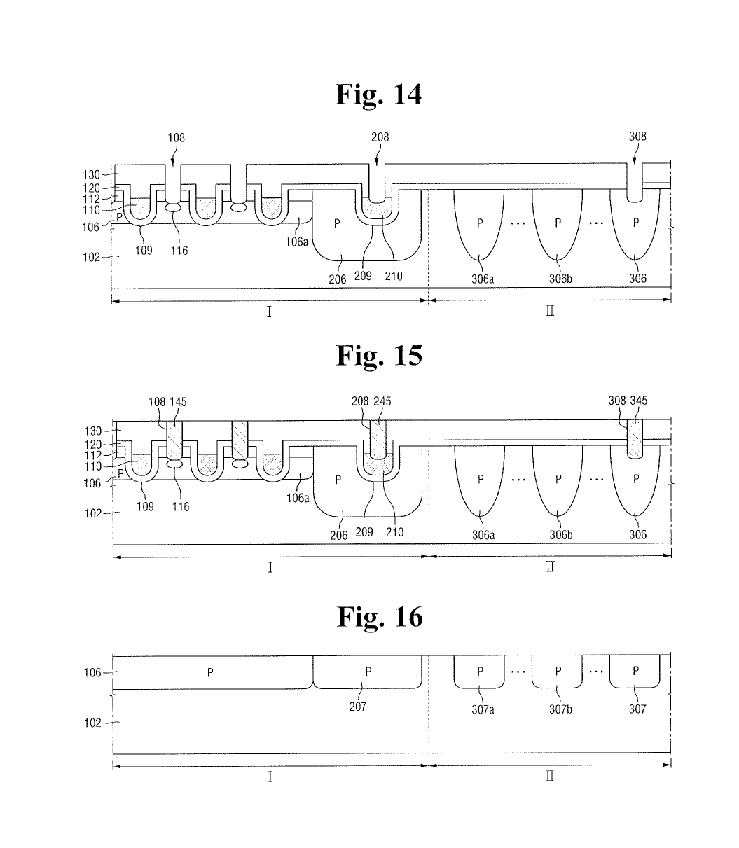

Referring to FIG. 14, the first contact hole 108, the second contact hole 208, and the third contact hole 308 are formed. The first contact hole 108, the second contact hole 208, and the third contact hole 308 are formed to pass through the interlayer insulating film 130 (or the field plate insulating film 330) and through part of the substrate 102. As described above, the first contact hole 108, the second contact hole 208, and the third contact hole 308 are formed simultaneously. That is, the first contact hole 108, the second contact hole 208, and the third contact hole 308 may be formed to an equal depth. Next, the high concentration body region 116 is formed under the first contact hole 108 without using an additional mask.

Referring to FIG. 15, the first contact 145, the second contact 245, and the third contact 345 are formed in the first contact hole 108, the second contact hole 208, and the third contact hole 308, respectively. The first contact 145, the second contact 245, and the third contact 345 are formed simultaneously. Therefore, the first contact 145, the second contact 245, and the third contact 345 may be formed of the same material and to an equal thickness.

Referring back to FIG. 2, a source metal 140 and a gate metal 240 are formed on the interlayer insulating film 130, and a field plate 340 is formed on the field plate insulating film 330. Here, the source metal 140, the gate metal 240, and the field plate 340 are formed simultaneously. The source metal 140, the gate metal 240, and the field plate 340 may be formed of the same material and to an equal thickness. In addition, the drain metal 150 is formed on the backside of the substrate 102.

A method of fabricating the semiconductor device according to the fifth embodiment will now be described with reference to FIG. 16. FIG. 16 is a cross-sectional view illustrating intermediate stages included in a method of fabricating the semiconductor device according to the fifth embodiment. For simplicity, the following description will focus on differences between FIGS. 11 and 16.

Referring to FIG. 16, the body region 106 is formed by implanting impurities of the first conductivity type into the substrate 102. Then, the connection junction 206 and field diffusion junctions 307, 307a, and 307b are formed by implanting impurities of the first conductivity type into the substrate 102. As described above, the connection junction 206 and the field diffusion junctions 307, 307a, and 307b may be formed to a depth equal to a depth of the body region 106 and have a higher concentration than the body region 106. That is, the connection junction 206 and the field diffusion junctions 307, 307a, and 307b may be implanted to a higher concentration than the body region 106. Subsequent processes are substantially identical to those described above with reference to FIGS. 12 through 15.

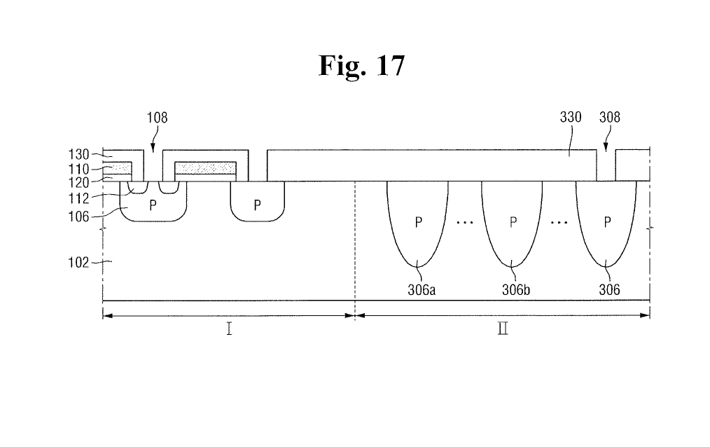

A method of fabricating the semiconductor device according to the sixth embodiment will now be described with reference to FIGS. 17 and 7. FIG. 17 is a cross-sectional view illustrating intermediate stages in a method of fabricating the semiconductor device according to the sixth embodiment.

Referring to FIG. 17, the planar transistor 101 is formed in the first region I. The planar transistor 101 may include the gate 110′ formed on the substrate 102 and the source 112′ formed in the substrate 102 to contact the gate 110′. Then, the interlayer insulating film 130 is formed, and, at the same time, the field plate insulating film 330 is formed. In other words, the interlayer insulating film 130 is used as the field plate insulating film 330.

Then, the first contact hole 108 is formed, and, at the same time, the third contact hole 308 is formed. Therefore, the depth of the first contact hole 108 may be equal to the depth of the third contact hole 308.

Referring back to FIG. 7, the first contact 145 is formed in the first contact hole 108, and the third contact 345 is formed in the third contact hole 308. The first contact 145 and the third contact 345 are formed simultaneously. Then, the source metal 140 is formed on the first contact 145, and the field plate 340 is formed on the third contact 345. The source metal 140 and the field plate 340 are formed simultaneously.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate including a first region and a second region;
a trench-gate transistor in the first region, the trench-gate transistor including:
a first trench in the substrate,
a gate filling at least part of the first trench, and
a source in the substrate and on each sidewall of the first trench;
a first field diffusion junction in the second region;
an interlayer insulating film on the substrate, the interlayer insulating film covering the trench-gate transistor and the first field diffusion junction;
a first contact in the first region, the first contact passing through the interlayer insulating film and contacting the source; and
a second contact in the second region, the second contact passing through the interlayer insulating film and contacting the first field diffusion junction, the first contact and the second contact having an equal height and including a same material.

2. The semiconductor device as claimed in claim 1, wherein the first contact and the second contact are fabricated simultaneously.

3. The semiconductor device as claimed in claim 1, wherein each of the first contact and the second contact further passes through part of the substrate.

4. The semiconductor device as claimed in claim 1, further comprising a source metal on the first contact and a field plate on the second contact, the source metal and the field plate having an equal thickness and include a same material.

5. The semiconductor device as claimed in claim 1, further comprising a second field diffusion junction in the second region, the second field diffusion junction being interposed between the trench-gate transistor and the first field diffusion junction.

6. The semiconductor device as claimed in claim 5, further comprising a third contact in the second region, the third contact passing through the interlayer insulating film and through part of the substrate to contact the second field diffusion junction.

7. The semiconductor device as claimed in claim 1, wherein a surface of the interlayer insulating film is planarized.

8. The semiconductor device as claimed in claim 1, further comprising a body region around the gate in the first region, the source being in the body region.

9. The semiconductor device as claimed in claim 8, wherein the body region has a first depth, and the first field diffusion junction has a second depth different from the first depth.

10. The semiconductor device as claimed in claim 8, wherein the body region has a first concentration, and the first field diffusion junction has a second concentration different from the first concentration.

11. The semiconductor device as claimed in claim 8, wherein the body region is formed to a first depth and a first concentration, and the first field diffusion junction is formed to a second depth which is greater than the first depth and to a second concentration which is lower than the first concentration.

12. The semiconductor device as claimed in claim 8, wherein the body region has a first depth and a first concentration, and the first field diffusion junction has a second depth equal to the first depth and a second concentration higher than the first concentration.

13. The semiconductor device as claimed in claim 8, further comprising a high concentration body region in the body region, the high concentration body region contacting a bottom surface of a contact hole.

14. The semiconductor device as claimed in claim 1, further comprising a gate connector in the first region and configured to provide a gate voltage to the gate, the gate connector including a second trench in the substrate and a conductor filling at least part of the second trench.

15. The semiconductor device as claimed in claim 14, wherein the interlayer insulating film covers the gate connector and further comprises a third contact, the third contact passing through the interlayer insulating film and through part of the conductor to contact the conductor.

16. The semiconductor device as claimed in claim 15, wherein the first through third contacts have equal heights and include a same material.

17. The semiconductor device as claimed in claim 15, further comprising:
a source metal on the first contact;
a field plate on the second contact; and
a gate metal on the third contact, the source metal, the field plate, and the gate metal having equal thicknesses and including a same material.

18. The semiconductor device as claimed in claim 15, further comprising a connection junction in the first region, the gate connection being in the connection junction.

19. The semiconductor device as claimed in claim 18, wherein the connection junction and the first field diffusion junction have an equal depth and an equal concentration.

20. A semiconductor system, comprising:
a transformer; and
a switching device connected to a secondary winding of the transformer, the switching device including the semiconductor device of claim 1.

21. A semiconductor device, comprising:
a substrate including a first region and a second region;
a trench-gate transistor in the first region, the trench-gate transistor including:
a first trench in the substrate,
a gate filling at least part of the first trench, and
a source in the substrate and on each sidewall of the first trench;
an interlayer insulating film on the first region, the interlayer insulating film covering the trench-gate transistor;
a first field diffusion junction in the second region;
a field plate on the first field diffusion junction; and
a field plate insulating film between the first field diffusion junction and the field plate, the field plate insulating film having a thickness equal to a thickness of the interlayer insulating film, and including a same material as the interlayer insulating film.

22. A semiconductor device, comprising:
a substrate including a first region and a second region;
a trench-gate transistor in the first region, the trench-gate transistor including:
a first trench in the substrate,
a gate filling at least part of the first trench, and
a source in the substrate and on each sidewall of the first trench;
a connection junction in the first region;
a gate connector in the connection junction of the first region and configured to provide a gate voltage to the gate, the gate connector including a second trench in the substrate and a conductor filling at least part of the second trench; and
a first field diffusion junction in the second region, the connection junction and the first field diffusion junction having an equal depth and an equal concentration.

23. A method of fabricating a semiconductor device, the method comprising:
providing a substrate including a first region and a second region;
forming a body region in the first region and a first field diffusion junction in the second region;
forming a transistor in the first region, the transistor including a gate and a source in the substrate and around the gate;
forming an interlayer insulating film on the substrate to cover the transistor and the first field diffusion junction;
forming a first contact in the first region to pass through the interlayer insulating film and contact the source; and
forming a second contact in the second region to pass through the interlayer insulating film and contact the first field diffusion junction, the first contact and the second contact being formed simultaneously.

24. The method as claimed in claim 23, wherein forming the transistor includes forming a trench-gate transistor, the trench-gate transistor including a first trench formed in the substrate, the gate filing at least part of the first trench, and the source in the substrate and on each sidewall of the first trench.

25. A semiconductor device, comprising:
a substrate including an active region and a termination region, the substrate including a second conductivity type;
pillars in the active region and in the termination region, the pillars including a first conductivity type;
an interlayer insulating film on the active region; and
a field plate on the termination region, the field plate having a thickness equal to a thickness of the interlayer insulating film, and including a same material as the interlayer insulating film.

26. A semiconductor device, comprising:
a substrate including a first region and a second region;
a transistor in the first region;
a first field diffusion junction in the second region;
an interlayer insulating film on the substrate, the interlayer insulating film continuously extending to cover the transistor and the first field diffusion junction, an upper surface of the interlayer insulating film above the transistor and the first field diffusion junction being completely parallel to a bottom of the substrate;
a first contact in the first region, the first contact passing through the interlayer insulating film to contact a source of the transistor; and
a second contact in the second region, the second contact passing through the interlayer insulating film to contact the first field diffusion junction, the first contact and the second contact having an equal height and including a same material.

27. The semiconductor device as claimed in claim 26, wherein an entire surface of the interlayer insulating film is flat and parallel to a bottom of the substrate.

28. The semiconductor device as claimed in claim 27, wherein upper surfaces of the first and second contacts are level with the upper surface of the interlayer insulating film.

29. The semiconductor device as claimed in claim 27, further comprising a source metal on the first contact and a field plate on the second contact, the source metal and the field plate having an equal thickness and include a same material.

30. The semiconductor device as claimed in claim 29, wherein the source metal contacts the first contact and the interlayer insulating film, and the field plate contacts the second contact and the interlayer insulating film.
